(19) United States
(12) Patent Application Publication
(10) Pub. No.: US 2003/0052319 A1
(43) Pub. Date: Mar. 20, 2003

(54) Fixture for multiple known good die processing

(76) Inventors: Hsing-Hsin Chen, Taipei Hsien (TW); Wan Soo Chee, Davis, CA (US)

Correspondence Address: HOGAN & HARTSON L.L.P., 500 S. GRAND AVENUE, SUITE 1900, LOS ANGELES, CA, 90071-2611, US

(21) Appl. No.: 10/230,971

(22) Filed: Aug. 29, 2002

Related U.S. Application Data
(63) Continuation-in-part of application No. 09/691,454, filed on Oct. 18, 2000.

(51) Int. Cl. H01L 23/58

(52) U.S. Cl. 257/48

(57) ABSTRACT

Integrated circuit device probing, testing and burn-in are performed in parallel before device packaging. A multiple die carrier has insets for holding dies with respect to a probe tip substrate, which has an array of contacts arranged to contact test pads on the dies to be tested within the die carrier. A top cover includes a set of pogo pins or similar pressure devices corresponding in number and position to the dies within the die carrier. When the top cover is positioned over the die carrier, the pressure devices on the top cover individually apply pressure to the corresponding dies within the die carrier, thereby holding each die against the corresponding contacts of the probe tip substrate. The fixture has locking mechanisms to hold the top cover, die carrier and probe tip substrate together so as to be stable during testing and burn-in.

### RELATED APPLICATION

This application claims priority as a continuation in part of copending U.S. patent application Ser. No. 09/691,454, entitled “Method and Apparatus for Multiple Known Good Die Processing,” which application is hereby incorporated by reference in its entirety.

### BACKGROUND

1. Field of the Invention

This invention generally relates to a fixture and method for burn-in and testing a bare integrated circuit die or, more preferably, for burn-in and testing in parallel a plurality of bare integrated circuit dies. Most preferably, the invention provides a fixture and method for the parallel probing, testing and burn-in of a plurality of bare integrated circuit dies. Particularly preferred embodiments of the present invention are particularly well adapted for the probing, testing and burn-in of memory devices.

2. Discussion of the Related Art

Traditional wafer probing techniques use a probe card on which is mounted a plurality of probe needles. The probe needles are mounted on a support base with adhesive that holds the needles in fixed positions to form an array of probe needles. The array of probe needles is arranged to match the arrangement of bonding pads of the integrated circuit to be tested. Probe needles need to be aligned to the bonding pads of the integrated circuit under test and need to remain in alignment through many thermal or other testing cycles. Alignment of the needles must be accomplished both with respect to the horizontal registration of the needles with respect to the bonding pads and vertical positioning of the tips of the probe needles with respect to the surfaces of the bonding pads.

For probing and testing to be effective for modern semiconductor device manufacturing techniques using large diameter wafers, probing and testing are done in parallel. That is, probing and testing are performed on several dies at once. The traditional wafer probing process has limitations due to the physical size of the array of probe needles and the layout of the bonding pads to be probed. Bonding pads for the integrated circuits are spaced closely together on the integrated circuits and consequently on the wafer. The physical space constraints on bringing many sets of probe needles into contact with the bonding pads of multiple integrated circuits limit the scaling possible with probe needle testing. Because of this, the typical probe needle testing system is limited to testing in parallel sixteen dies on the wafer at one time.

Wafer probing is an important process that can identify the quality of an integrated circuit before assembly. Identifying defective integrated circuit devices prior to assembly avoids unnecessary packaging and assembly costs.

Burn-in is a process that is used for testing the reliability of an integrated circuit. Some integrated circuits, such as memory devices, exhibit selected failure modes only after years of proper operation. Obviously, production testing cannot continue for years to determine if an integrated circuit is going to fail prematurely. Consequently, elevated temperature and elevated operating voltages are applied to the integrated circuits such as memory devices to accelerate the aging process and to ascertain the expected reliability of the integrated circuits. This form of testing is known as burn-in and generally is performed after wafer sorting is complete. Burn-in testing can both pinpoint chips that are likely to suffer early failure and can also help determine the overall failure rate that can be expected for a particular batch of devices.

The purpose of reliability testing is to quantify the expected failure rate of a device at various points in its life span. Fundamental principles of reliability engineering predict that the failure rate for a group of devices will follow the bathtub-shaped curve. This well-known curve is divided into three regions: infant mortality, random failure, and wear out failure. In the infant mortality portion of the curve (one steeply-sloped side of the “bathtub”), there is an initially high failure rate due to certain types of failure that diminishes to a baseline “random” failure rate. The random failure portion of the curve (the bottom of the bathtub) extends through the expected life of the device and is characterized by random failure mechanisms. The wear out failure portion of the curve (the other steeply-slope side of the bathtub) is characterized by a failure rate that rises above the random failure rate and end-of-life failure mechanisms. The bathtub curve model of failure rates is generally viewed as an appropriate prediction of integrated circuit failures.

Integrated circuit manufacturers use burn-in and associated testing to screen out infant mortality failures from newly manufactured wafers. As discussed, burn-in and burn-in testing are performed at elevated temperatures and operating voltages to achieve accelerated identification of expected failures. Typically, packaged memory devices require eight to twenty-four hours of burn-in processing at 125° C. or a higher temperature to provide the desired level of reliability.

If burn-in processing is implemented after package assembly, assembly time and cost are likely to be wasted, particularly when using CSP (chip scale package) technology. In light of the high cost of packaging chips, it is desirable to not package chips that burn-in testing will identify as likely to fail and especially to not package chips that will actually fail during burn-in testing. The present trend in packaging integrated circuits is to make greater use of flip chip and MCM (multi chip module) packages, which can be even more expensive than CSP packages. Consequently, the cost of materials and assembly is expected to increase in the future. There is a consequent need to achieve reliable testing of chips before packaging, for example, using the known good die solution.

Recent developments in addressing this problem utilize (1) wafer level burn-in and (2) BIST (built in self-test) to replace real burn-in. However, wafer level burn-in introduces physical stress to the wafer and the test assembly. BIST requires the designer and manufacturer to change the chip design and enlarge the die size, both of which increase costs and introduce new types of failures. Due to the problem of stress test and burn-in BIST, it is possible that the wafer level burn-in solution and the BIST solution might be unable to be entirely effective in screening out the infant mortality failures.

### SUMMARY OF THE PREFERRED EMBODIMENTS

There is consequently a need for more efficient and flexible testing techniques and for fixtures that better facilitate testing.

An aspect of the present invention provides a multiple known good die fixture including a die carrier having a plurality of insets adapted for holding a plurality of dies having an integrated circuit formed thereon. The fixture further includes a probe tip substrate having an array of contacting tips that are adapted to couple to contacts on a plurality of dies when the probe tip substrate is assembled with the die carrier carrying the plurality of dies. The probe tip substrate further has an array of contact terminals on a second surface for coupling signals to or from the contacts of dies held within the die carrier. The fixture includes an array of pressure devices arranged to apply individual pressure to dies held laterally by the die carrier and to hold the contacts on the dies held within the die carrier to corresponding contacts on the probe tip substrate.

Another aspect of the invention provides a multiple known good die fixture including a die guide having a plurality of die cavities adapted for holding a corresponding plurality of dies. The fixture includes a probe tip substrate adapted to cooperate with the die carrier. The probe tip substrate has contacting tips on a first surface that are adapted to touch contacts on a plurality of dies when the probe tip substrate is assembled with the die carrier carrying the plurality of dies. The probe tip substrate further has an array of contact terminals on a second surface with each of the contact terminals coupled to a corresponding one of the array of contacting tips. A housing is provided for holding the die guide and probe tip substrate in contact with each other and holding an array of dies when in a test configuration. The housing applies pressure around a circumference of the die carrier to hold the die carrier substrate in fixed relation to the probe tip substrate. The fixture includes a top cover for the housing. The top cover is provided on a side of the die carrier opposite the probe tip substrate and having an array of pressure devices arranged to hold individual dies within the die carrier against the probe tip substrate.

Another aspect of the present invention provides a method of multiple known good die testing including providing a die carrier having a plurality of insets adapted for holding a plurality of dies having an integrated circuit formed thereon. A number of dies are positioned within the plurality of insets. A probe tip substrate is positioned adjacent the die carrier. The probe tip substrate has an array of contacting tips that are adapted to couple to contacts on the number of dies within the insets of the probe tip substrate. The probe tip substrate further has an array of contact terminals on a second surface for coupling signals to or from the contacts of dies held within the die carrier. An array of pressure devices is positioned so as to apply individual pressure to the dies held laterally by the die carrier and to hold the contacts on the dies held within the die carrier to corresponding contacts on the probe tip substrate.

### BRIEF DESCRIPTION OF THE DRAWINGS

FIG. 1 provides perspective views of the components of a multiple known good die-testing fixture in accordance with aspects of the present invention.

FIG. 2 provides a partial assembly of portions of the fixture of FIG. 1.

FIG. 3 illustrates in perspective view two components of the multiple known good die-testing fixture of FIG. 1.

FIG. 4 illustrates in perspective view a subassembly of components of the multiple known good die-testing fixture of FIG. 1.

FIGS. 5a and 5b illustrate perspective views of components of alternate subassemblies of the multiple known good die-testing fixture of FIG. 1.

FIG. 6 illustrates in perspective view a subassembly of components of the multiple known good die-testing fixture of FIG. 1.

FIG. 7 illustrates in exploded view a cross sectional view of a portion of a probe tip substrate that might be used in the FIG. 1 fixture.

### DETAILED DESCRIPTION OF THE PREFERRED EMBODIMENTS

Particularly preferred embodiments of the present invention provide an apparatus and a method for multiple known good die testing and burn-in. Preferred methods and apparatus provide simultaneous testing of one or more dies sawed from a wafer and placed within a multiple die carrier in accordance with the present invention. The die carrier is positioned over a probe tip substrate so that dies within the carrier are preferably contacted by the probe tips or bumps arranged on the upper surface of the probe tip substrate. A top cover includes a set of pogo pins, rubber tips or similar pressure devices corresponding in number and position to the dies within the die carrier. The top cover is positioned over the die carrier and probe tip substrate so that pressure devices individually apply pressure to the corresponding dies within the die carrier. Pressure is also applied to urge the top cover toward the probe tip substrate, thereby holding each die against the corresponding contacts of the probe tip substrate.

Preferably the fixture is arranged to hold the probe tip substrate, die carrier and top cover in a stable, sandwiched configuration so that the pogo pins, rubber tips or other pressure devices apply a uniform pressure to the corresponding dies to hold the dies against the probe tip substrate. Most preferably the fixture locks to apply a uniform pressure between the probe tip substrate and the top cover and further to fix the lateral (horizontal) position of the die carrier, probe tip substrate and dies throughout a testing and burn in process.

In certain preferred implementations, the predominate materials for the carrier substrate, the probe tip substrate, the top cover are preferably selected to have a coefficient of thermal expansion (CTE) similar to that of the silicon integrated circuit devices. These materials might also be chosen to have a low dielectric constant to make high frequency testing easier.

Preferably, the multiple known good die apparatus has a plurality of probe tips or bumps formed on the bottom of the probe tip substrate so that the probe tips or bumps are arranged in an array matching the test pads of the integrated circuit device to be tested. In using a multiple known good die testing system in accordance with the present invention, a device formed on a die is placed into the die carrier and onto the contacts of the probe tip substrate. Additional devices may be loaded into the die carrier. The die carrier and probe tip substrate might be vibrated for fine alignment of the array of probe tips or bumps with respect to the array of test pads for each of the integrated circuits to be tested. Then the top cover and its array of pressure applying devices are positioned over the die carrier. The top cover, the die carrier and the probe tip substrate are pressed together to make good contact between the bonding pads and probe tips or bumps. After contact is made, the fixture may be locked to hold the top cover, die carrier and probe tip substrate in position, and the integrated circuits on the dies are electrically tested and burned-in.

These and other aspects of preferred embodiments of the present invention are now described in further detail with respect to the figures.

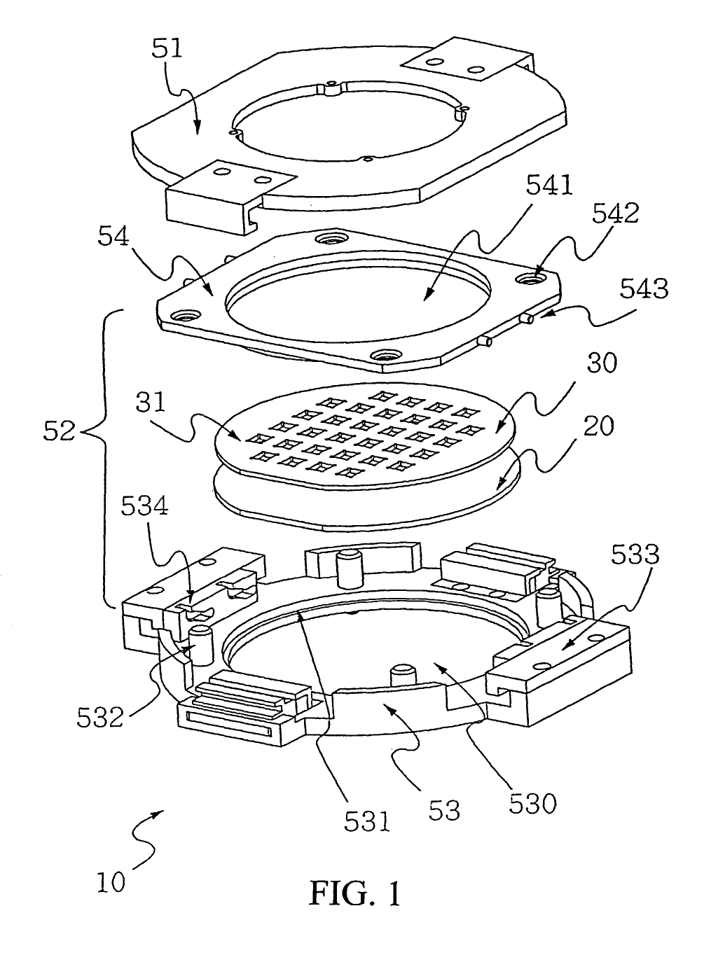

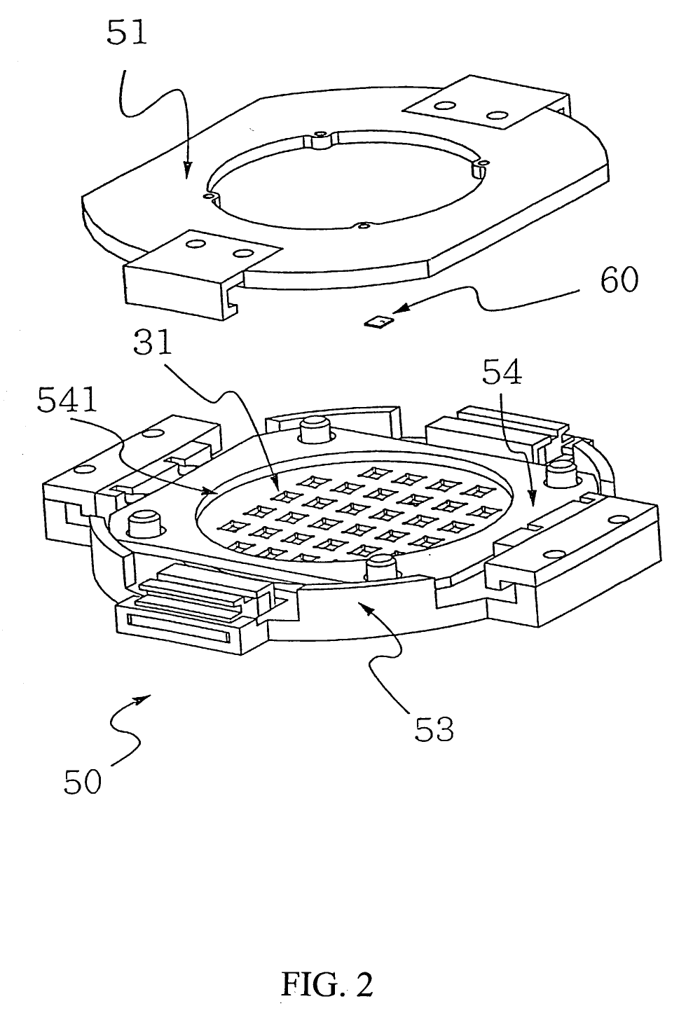

FIG. 1 provides a perspective view of the component parts of a cassette or fixture for simultaneously testing and burning-in a plurality of integrated circuit dies. The illustrated fixture is designed for use with presently available testing equipment to facilitate that equipment's simultaneous testing of a plurality (for example, 32) of dies. FIG. 1 illustrates an implementation of the fixture as a sandwich of various components. Dies to be tested are held in a die guide 30 that interfaces with a probe tip substrate 20 to hold the dies in place and to facilitate electrical connections to the dies under test. In FIG. 1, device 10 includes top cover 51 and assembly 52, which in turn includes housing 53 and fixture cover 54. The housing 53 has a concentric opening 530 to accommodate a probe tip substrate 20, with the concentric opening exposing the bottom surface of the probe tip substrate 20. Contacts, bumps or similar elements are provided on the bottom surface of the probe tip substrate 20 to connect the dies under test to the test circuitry of external testing equipment. The opening 530 within the housing 53 has a notch 531 extending around the circumference of the opening 530 in the housing 53 and sized to accept the probe tip substrate 20 and ceramic die guide 30. The notch 531 accurately positions the probe tip substrate 20 and ceramic die guide 30 with respect to the test equipment. When the probe tip substrate 20 and ceramic die guide 30 are put into the housing 53, notch 531 most preferably aligns and keeps the substrate 20 and guide 30 precisely in the required position and orientation. There is a plurality of hollow die cavities 31 in the ceramic die guide 30. The shape and size of the die cavities 31 match that of dies 60 sawed from a wafer so that a die cavity 31 can hold a die 60 firmly in position. Fixture cover 54 has a concentric opening 541 through which the die 60 can be placed into the die cavity 31 of the ceramic die guide 30 after assembly of the fixture. FIG. 2 shows a more complete assembly of the fixture of FIG. 1 with only the top guide 51 spaced from the assembly.

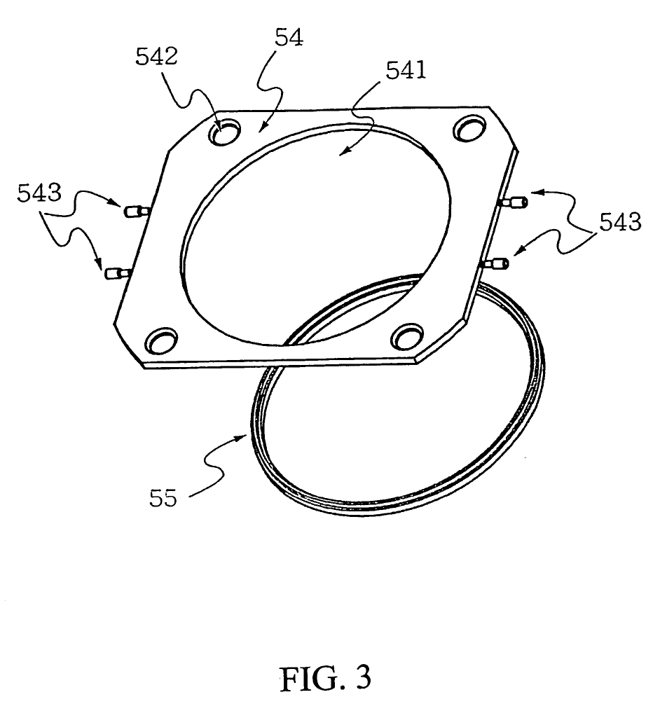

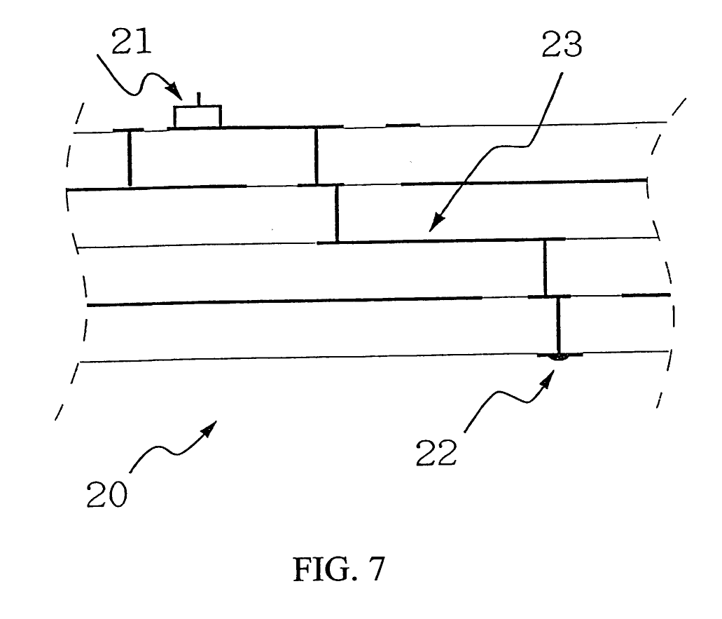

Assembling the FIG. 1 cassette from its components begins by turning the probe tip substrate 20 upward, so that micro tips 21 face up (shown in FIG. 7), and placing substrate 20 into the notch 531 of the housing 53. The ceramic die guide 30 is placed into the notch 531 and arranged to position it in close contact with the probe tip substrate 20. The illustrated die cavities 31 of the ceramic die guide 30 accommodate a plurality of dies 60. Assembly continues by placing the fixture cover 54 on top of die guide 30 and fastening the locks or latches with housing 53. Cushion 55 shown separately in FIG. 3 is installed on the lower edge of the fixture cover 54 and generally corresponds in shape to the shape of the opening 541. When the fixture cover 54 is latched onto the housing 53, the cushion 55 helps to apply uniform pressure to the ceramic die guide 30 and probe tip substrate 20. There are a plurality of housing guide pins 532 in the housing 53 to match with the fixture cover guide pin holes 542 on the fixture cover 54 to hold the fixture cover 54 and housing 53 in a fixed horizontal position when the fixture cover 54 and housing 53 are latched together.

The fixture cover 54 has fixture cover guide pins 543 adjacent its edges. There are two sliding covers 533 on the housing 53, each of which has openings to a pair of serpentine slots 534 exposed on the upper surface and extending along the inner faces of the sliding covers 533. The serpentine slots 534 are adapted in their size and in their shape to engage pins 543 of the fixture cover 54. The fixture cover 54 is mounted to the sliding covers 533 by placing the pins 543 in their corresponding openings of the serpentine slots 534 and moving the sliding covers 54 laterally. As the sliding covers 533 are moved laterally, the pins 543 move along the serpentine slots 534 and are guided downward. By moving the sliding covers 533 laterally, the pins 543 move downward and force the fixture cover 54 down to the housing 53. Of course, by moving the sliding covers 533 in the opposite direction, the fixture cover 54 is lifted from the housing 53, as would occur in disassembly of the die testing fixture.

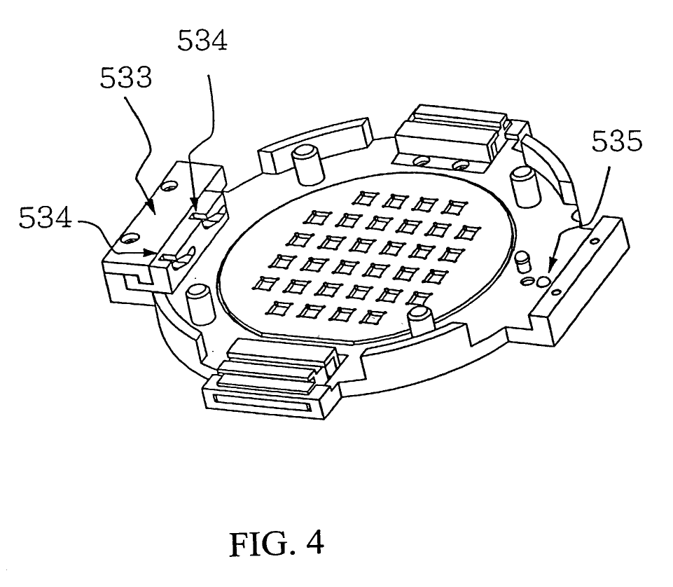

There are bumps 535 on the upper surface of the housing positioned so that they will be adjacent the bottom surface of the sliding covers 533 when they are in their laterally-displaced, locked position adjacent the upper surface of the housing 53. One of these bumps is shown in FIG. 4; sliding cover 533 covers the other bump. When the sliding covers 533 are positioned to hold the pins 532 near the surface of the housing 53, the bottom surface of the sliding cover 533 engages a corresponding one of the bumps 535 to hold the sliding cover 533 in place. There may, in certain embodiments, be corresponding indentations in the bottom surface of the sliding covers 533 to receive the bumps 535, facilitating the locking of the sliding covers 533 in a position that holds the fixture cover 54 close to the upper surface of the housing 53.

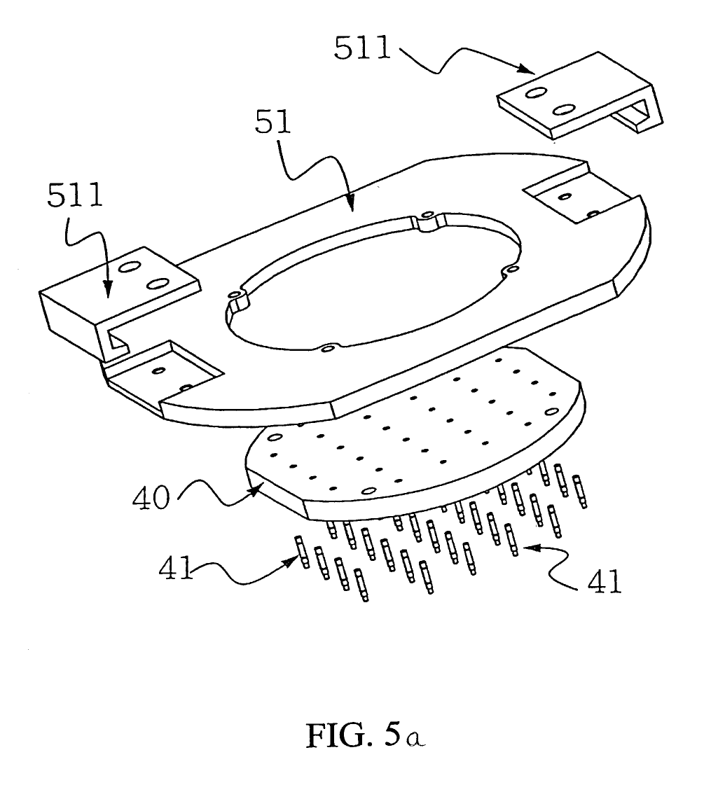

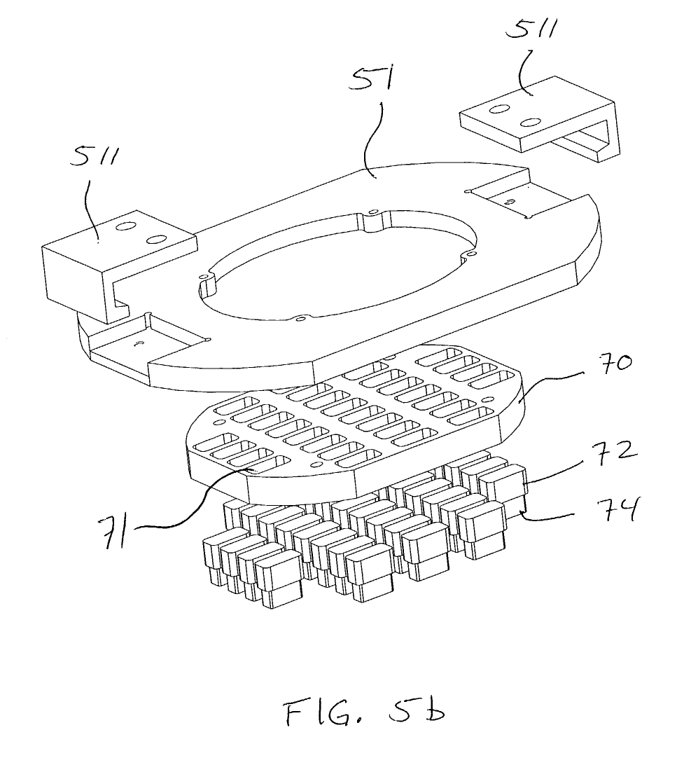

During testing, a pick and place device, which is conventionally used for die placement, preferably places a plurality of dies 60 to be tested into corresponding die cavities 31 as illustrated generally in FIG. 2. The illustrated embodiment preferably includes a tip cover holder 40 that attaches to the central part of the top cover 51 as shown in FIG. 5a. There are multiple independent die pogo pins 41 on the lower surface of the tip cover holder 40. In assembling tip cover holder 40 and ceramic die guide 30, each die pogo pin 41 preferably is positioned on top of a corresponding die 60 within the die cavities 31 to push the corresponding die 60 into tight contact with probe tip substrate 20.

An alternate tip cover holder 70 is illustrated in FIG. 5b. The tip cover holder interfaces with the top cover as the assembly of FIG. 5a, but provides an array of rubber tips corresponding to the array of die positions to be tested so that the array of rubber tips provides appropriate individualized pressure to dies within the die positions. Tip cover holder 70 has openings 71 to receive the bases 72 of rubber tips 74 and hold the rubber tips laterally and vertically in place corresponding to the die positions. Rubber tips 74 are selected to be a high temperature rubber capable of resiliency and durability at testing and burn-in temperatures and after repeated thermally cycling.

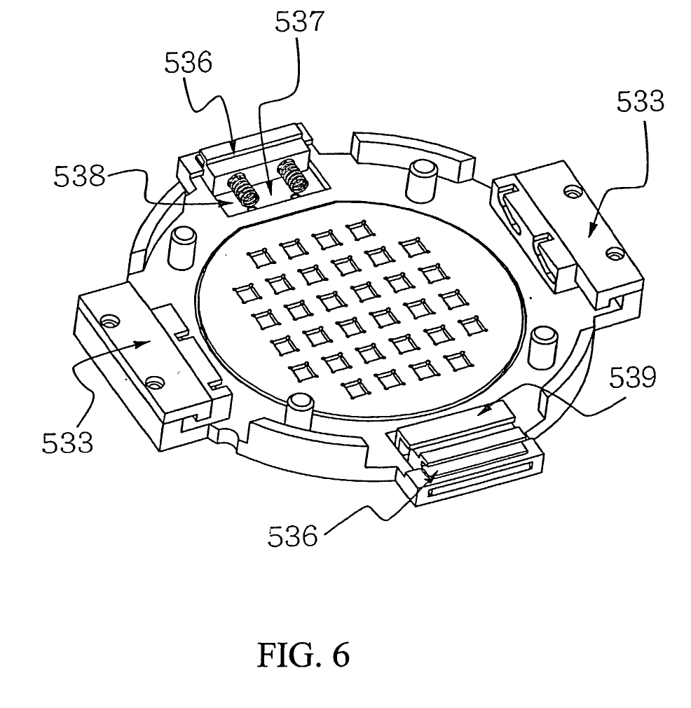

Referring to FIGS. 1 and 6, two parallel sliding lockers 536 are provided as parts of sliding jigs on either side of the housing 53, which are preferably spaced away from the sliding cover 533. Each sliding jig includes a sliding locker 536 with an opening or concave outside, a sliding groove 537 for directing and controlling the sliding locker position, a pair of springs 538 and a sliding locker cover 539. The sliding locker 536 can move inward or outward with respect to the housing 53 horizontally within the path defined by the sliding groove 537 and by the sliding locker cover 539. When there is no external force applied to it, each of the sliding lockers 536 is extended outward by its corresponding springs 538. On the edge of the top cover 51 there is a pair of fixed lockers 511 corresponding to a pair of sliding jigs on opposing rims of the housing 53. The fixed lockers 511 on the top cover 51 have an extension or lip adapted to be received by the opening or concave in the sliding locker 536, thereby locking the top cover 51 to the sliding locker 536 on the housing 53 when the sliding lockers 536 engage the lips on the fixed lockers.

To assemble the top cover 51 and housing 53, external force is applied to move the sliding locker 536 inward of the housing 53 and then pressing the fixed locker 511 of the top cover 51 down to the same level of the sliding locker 536 of the housing 53. The sliding lockers 536 are forced outward by the springs 538 to lock the fixed lockers 511 so that the housing 53 holds the top cover 51 firmly in place when the external force is released. The top cover 51 corresponding to the housing 53 preferably is designed to keep it from moving with respect to the housing 53 after assembly. To unlock the top cover 51 and the housing 53 an external force is applied to push the sliding locker 536 inward to the housing 53 and then the top cover 51 is lifted to remove it and continue disassembly.

The multiple known good die testing fixture is formed by assembling two main subassemblies and then assembling the two subassemblies together. The lower subassembly is assembled, dies are placed in the die carrier and the upper subassembly is assembled to the lower subassembly before the fixture is used for multiple known good die testing or a burn-in process. A first process assembles tip substrate 20 and ceramic die guide 30 in proper order and direction within the notch 531 of the housing 53. Fixture cover 54 is assembled with the cushion 55 and is then placed on the ceramic die guide 30. Fixture cover guide pins 543 of the fixture cover 54 are inserted into the serpentine slots 534 of the sliding covers 533. Moving the sliding cover 533 forces the fixture cover 54 to hold the probe tip substrate 20 and ceramic die guide 30 tightly in place within the housing 53. Furthermore, the tip cover holder 40 with the die pogo pins 41 is locked down on the central part of the top cover 51. Alternately, the tip cover holder 70 of FIG. 5b with its rubber tips 74 is locked down on the central part of top cover 51.

Dies to be tested 60 are put into the die cavities of the ceramic die guide 30 separately as shown in FIG. 2. This might be accomplished using a conventional pick and place machine. After all of the dies are placed within the die guide 30, the second subassembly including top guide 51 together with the tip cover holder 40 or 70 is positioned over the first subassembly. By locking a pair of the fixed lockers 511 of the top cover 51 with a pair of the sliding jigs of the housing 53, the second subassembly is fixed into the first subassembly. Die pogo pins 41, which are on the lower surface of the tip cover holder 40, align to each die 60 to be tested in the cavity 31 and apply pressure against the dies 60 so that the probe tips 21 of the probe tip substrate 20 and the bonding pads under the dies 60 are in good contact. Of course, while pogo pins are illustrated in this embodiment other pressure devices such as leaf springs or resilient materials might be used to apply individual pressure to hold the dies against the respective portions of the probe tip substrate. Thus, when the tip cover 70 of FIG. 5b is used, the rubber tips 74 align to each die 60 to be tested in its cavity 31 and the rubber tips apply individual pressure to hold the dies against respective portions of the probe tip substrate.

Using contacts exposed within the central opening 530 of the housing 53, the probe tip substrate 20 of the assembled multiple known good die (“MKGD”) testing fixture couples signals from the test or other bonding pads of the integrated circuit on the die 60 under test to the conventional or other automated test equipment. Contact points 22 illustrated in FIG. 7 are formed on the bottom surface of probe tip substrate 20 to connect the signal lines within the probe tip substrate to the load board of the automated test equipment (ATE). Each of the probe tips 21 on the probe tip ceramic substrate 20 preferably is connected to a corresponding contact 22 on the lower surface of the probe tip substrate 20. Ground planes might be provided within the probe tip substrate 20 to shield signals, reduce cross talk and improve electrical signal pick up.

Probe tip substrate 20, ceramic die guide 30 and tip cover holder 40 are preferably made of a ceramic material having a coefficient of thermal expansion substantially equal to that of silicon or the material of the device to be tested. Preferably the ceramic material of each of these components has a relatively low dielectric constant to reduce coupling between adjacent signal lines, reduce impedance matching problems and to facilitate testing. It is further preferred that the ceramic be substantially hard so that the fixture has good durability.

The probe tips on the probe tip substrate could be vertical probe tips, any type of elastic probe tip 21 or bumps (not shown). Each probe tip 21 on the probe tip ceramic substrate 20 preferably is connected to a corresponding contact 22 on the lower surface of the probe tip substrate 20. Ground planes are recommended within the probe tip substrate 20 and preferably are placed to shield signals, reduce cross talk and improve electrical signal pick up.

Referring to FIG. 7, it is recommended that the internal layer of electrical circuits within the probe tip substrate 20 is an island structure 23. This island 23 allows for the probe tip substrate 20 to accommodate a device redesign or a device shrink of the type frequently performed to form additional devices on a single wafer. When such a device redesign occurs, the probe tips 21 or bumps can be ground off of the probe tip substrate and new probe tips or, similarly, bumps can be provided on the island 23, which now appears on the new lower surface of the probe tip substrate. This technique extends the life of a probe tip substrate, which can be a significant benefit in the rapidly changing integrated circuit business.

The probe tip substrate most preferably accommodates device redesign or device shrinks of the type frequently performed so additional devices are formed on a single wafer. Both redesign and device shrinks are common in the integrated circuit business. When such a device redesign or shrink is necessary, the probe tips or bumps on the upper surface of the probe tip assembly can be removed from the upper surface of the probe tip assembly. A new array of probe tips or bumps is formed to accommodate the contact pad arrangements of the new device design. This process can be repeated as needed to match the redesigned devices, extending the life of the probe tip assembly and accommodating the fast development and change of the integrated circuit business.

The present invention has been described here with respect to certain preferred embodiments thereof. Those of ordinary skill will appreciate that various modifications and alternate embodiments of the invention might be practiced without varying from the basic teachings of the present invention. As such, the present invention is not to be limited to the particular embodiments described here. Rather, the scope of the present invention is to be determined from the claims.

What is claimed:

1. A multiple known good die fixture, comprising:
a die carrier having a plurality of insets adapted for holding a plurality of dies having an integrated circuit formed thereon;
a probe tip substrate having an array of contacting tips that are adapted to couple to contacts on a plurality of dies when the probe tip substrate is assembled with the die carrier carrying the plurality of dies, the probe tip substrate further having an array of contact terminals on a second surface for coupling signals to or from the contacts of dies held within the die carrier; and
an array of pressure devices arranged to apply individual pressure to dies held laterally by the die carrier and to hold the contacts on the dies held within the die carrier to corresponding contacts on the probe tip substrate.

2. The fixture of claim 1, wherein the die carrier and probe tip substrate are formed from materials capable of heating to a temperature appropriate to an integrated circuit burn-in process.

3. The fixture of claim 1, wherein the array of pressure devices are positioned by a top cover so that the pressure devices correspond to positions for dies within the die carrier.

4. The fixture of claim 3, wherein the top cover, die carrier and probe tip substrate are formed from materials capable of heating to a temperature appropriate to an integrated circuit burn-in process.

5. The fixture of claim 1, further comprising a housing adapted to receive the probe tip substrate and the die carrier during a testing or burn in operation.

6. The fixture of claim 5, wherein the housing, the probe tip substrate and the die carrier are joined together and held in fixed relationship prior to loading dies into the plurality of insets of the die carrier.

7. The fixture of claim 5, wherein the housing, the top cover, the probe tip substrate and the die carrier are joined together and held in fixed relationship for testing or burn in.

8. The fixture of claim 7, wherein the top cover, die carrier and probe tip substrate are formed from materials capable of heating to a temperature appropriate to an integrated circuit burn-in process.

9. A multiple known good die fixture, comprising:
a die guide having a plurality of die cavities adapted for holding a corresponding plurality of dies having an integrated circuit formed thereon;
a probe tip substrate adapted to cooperate with the die carrier, the probe tip substrate having an array of contacting tips on a first surface that are adapted to touch contacts on a plurality of dies when the probe tip substrate is assembled with the die carrier carrying the plurality of dies, the probe tip substrate further having an array of contact terminals on a second surface with each of the contact terminals coupled to a corresponding one of the array of contacting tips;
a housing for holding the die guide and probe tip substrate in contact with each other and holding an array of dies when in a test configuration, the housing applying pressure around a circumference of the die carrier to hold the die carrier substrate in fixed relation to the probe tip substrate; and
a top cover for the housing, the top cover provided on a side of the die carrier opposite the probe tip substrate and having an array of pressure devices arranged to hold individual dies within the die carrier against the probe tip substrate.

10. The fixture of claim 9, wherein the top cover comprises a set of pins resiliently coupled to the top cover and positioned on the top cover corresponding to the die cavities within the die carrier to hold dies in contact with the probe tip assembly,
wherein the die guide and probe tip substrate are formed from materials capable of heating to a temperature appropriate to an integrated circuit burn-in process.

11. The fixture of claim 9, wherein the housing assembles and lock to apply the pressure to the die carrier.

12. The fixture of claim 11, wherein the housing is separated from the die carrier by a resilient gasket.

13. A method of multiple known good die testing, comprising:
providing a die carrier having a plurality of insets adapted for holding a plurality of dies having an integrated circuit formed thereon;
positioning a number of dies within the plurality of insets;
positioning a probe tip substrate adjacent the die carrier, the probe tip substrate having an array of contacting tips that are adapted to couple to contacts on the number of dies within the insets of the probe tip substrate, the probe tip substrate further having an array of contact terminals on a second surface for coupling signals to or from the contacts of dies held within the die carrier; and
positioning an array of pressure devices arranged to apply individual pressure to the dies held laterally by the die carrier and to hold the contacts on the dies held within the die carrier to corresponding contacts on the probe tip substrate.

14. The method of claim 13, further comprising heating the array of pressure devices, the dies, and the die carrier to a temperature appropriate to an integrated circuit burn-in process.

16. The method of claim 13, wherein the array of pressure devices are positioned by a top cover so that the pressure devices correspond to positions for dies within the die carrier.

17. The method of claim 13, wherein the pressure devices are pogo pins.

18. The method of claim 13, wherein the pressure devices comprise resilient tips.

19. The method of claim 13, wherein the pressure devices include rubber tips.
